(19) United States
(12) Patent Application Publication
(10) Pub. No.: US 2013/0280859 A1
(43) Pub. Date: Oct. 24, 2013

(54) THIN-FILM TRANSISTOR AND METHOD FOR MANUFACTURING SAME

(71) Applicants: Jae-Ho Kim, Seoul (KR); Dong-Gun Oh, Gyeonggi-do (KR); Do-Hyun Choi, Gyeonggi-Do (KR); Jin-Wook Moon, Gyeonggi-do (KR)

(72) Inventors: Jae-Ho Kim, Seoul (KR); Dong-Gun Oh, Gyeonggi-do (KR); Do-Hyun Choi, Gyeonggi-Do (KR); Jin-Wook Moon, Gyeonggi-do (KR)

(21) Appl. No.: 13/977,725

(22) PCT Filed: Nov. 23, 2011
(86) PCT No.: PCT/KR2011/008975

§ 371 Date: Jun. 30, 2013

(30) Foreign Application Priority Data
Dec. 30, 2010 (KR) 10-2010-0139190
Aug. 18, 2011 (KR) 10-2011-0082199
Nov. 22, 2011 (KR) 10-2011-0122412

(51) Int. Cl. H01L 29/66

(52) U.S. Cl. CPC H01L 29/66969
USPC 438/104

(57) ABSTRACT

Provided are a thin film transistor and a method of manufacturing the same. The thin film transistor includes: a gate electrode; source and drain electrodes spaced apart in a up and down direction from the gate electrode and in a horizontal direction from each other; a gate dielectric formed between the gate electrode and the source electrode and between the gate electrode and the drain electrode; and an active layer formed between the gate dielectric and the source electrode and between the gate dielectric and the drain electrode, wherein the active layer is formed of at least two zinc oxide thin layers doped with an element.

### CROSS-REFERENCE TO RELATED APPLICATION

This application claims priority to Korean Patent Application Nos. 10-2010-0139190 filed on Dec. 30, 2010, 10-2011-0082199 filed on Aug. 18, 2011 and 10-2011-0122412 filed on Nov. 22, 2011 and all the benefits accruing therefrom under 35 U.S.C. §119, the contents of which are incorporated by reference in their entirety.

### BACKGROUND

The present disclosure relates to a thin film transistor and method of manufacturing the same, and more particularly, to a thin film transistor using a metal oxide semiconductor thin layer as an active layer, and a method of manufacturing the same.

A thin film transistor (TFT) is used as a circuit for independently driving each pixel in a liquid crystal display (LCD), an organic electro luminescence (EL) device, etc. The TFT is formed on a substrate together with a gate line and a data line. That is, the TFT includes a gate electrode, a gate dielectric, an active layer, a source electrode and a drain electrode. The gate electrode is formed from the gate line and the source and drain electrodes are formed from the data line.

Meanwhile, the active layer of the TFT functions as a channel between the gate electrode and the source/drain electrode, and is formed by using amorphous silicon or crystalline silicon. However, since a thin film transistor substrate using silicon should use a glass substrate, the thin film transistor substrate is heavy and not flexible and thus has a limitation that it cannot be used for a flexible display. To address this limitation, researches on metal oxide have been frequently performed in recent years.

Especially, research on a zinc oxide (ZnO) thin film is being actively performed. It is known that the ZnO thin layer has a characteristic in that crystal is easily grown even at a low temperature and ZnO thin layer is a superior material in securing high charge concentration and mobility. However, ZnO thin layer is unstable in terms of film quality when exposed to the atmosphere and thus has a disadvantage in that it deteriorates the stability of a thin film transistor. Also, ZnO thin layer may cause a problem in that off current is elevated or threshold voltage is changed due to excess carriers generated by oxygen defect.

To improve the film quality of the ZnO thin layer, indium gallium zinc oxide (hereinafter, referred to as ‘IGZO’) thin layer obtained by doping indium (in) and gallium (Ga) into ZnO thin layer has been proposed. IGZO thin layer is typically formed by sputtering using an IGZO target. In the case IGZO thin layer is formed by using a sputtering, and the composition of the IGZO thin layer is changed as the deposition of the IGZO thin layer progresses, so that the film quality of the IGZO thin layer formed sequentially may be not uniform. That is, since the crystal structure and grains of the IGZO target are irregular, the composition of the IGZO thin layer is changed as the deposition of the IGZO thin layer is progressed, so that the film quality is not uniform. Thus, thin film transistors which are manufactured in the same chamber and the same process have different characteristics, and thus the reliability of the thin film transistors is lowered. Also, the active layer may be formed in a plurality of layers each having a different composition if necessary. However, since the IGZO target is manufactured only in one composition, it is difficult to form an active layer having a multi-layer structure. That is, a multi-layered active layer each layer having a different composition cannot be formed by sputtering using the IGZO target.

### SUMMARY

The present disclosure provides a thin film transistor that can enhance stability by improving the film quality of an IGZO thin layer, and a method of manufacturing the same.

The present disclosure also provides a thin film transistor that can enhance reliability by allowing the composition of an IGZO thin layer not to be changed while a deposition process of the IGZO thin layer is progressed, and a method of manufacturing the same.

The present disclosure also provides a thin film transistor in which an IGZO thin layer may be formed in a multilayer structure and a composition ratio of each layer in the multilayer-structured IGZO thin layer may be controlled differently, and a method of manufacturing the same.

The present disclosure also provides a thin film transistor in which an IGZO thin layer used as an active layer in the thin film transistor is formed by a chemical vapor deposition such as an atomic layer deposition or the like, and a method of manufacturing the same.

In accordance with an exemplary embodiment, a thin film transistor includes: a gate electrode; source and drain electrodes spaced apart in a rip and down direction from the gate electrode and in a horizontal direction from each other a gate dielectric formed between the gate electrode and the source electrode and between the gate electrode and the drain electrode; and an active layer formed between the gate dielectric and the source electrode and between the gate dielectric and the drain electrode, wherein the active layer is formed of at least two zinc oxide thin layers doped with an element.

The doped element may be a Group III or IV element, and may be at least one of gallium, indium and tin.

The doped at least two zinc oxide thin layers may include at least one of an IGZO thin layer and an ITZO thin layer having a multilayer structure comprising at least two layers stacked.

The doped at least two zinc oxide thin layers may include a first zinc oxide thin layer formed by an ALD process, and a remaining zinc oxide thin layer other than the first zinc oxide thin layer formed by at least one of a pseudo ALD process, a cyclic CND process and a CND process.

The first zinc oxide thin layer may be formed at a side close to the gate electrode.

The doped at least two zinc oxide thin layers may be different in composition ratio.

The first zinc oxide thin layer may be higher in mobility and conductivity than the remaining zinc oxide thin layer, and the first zinc oxide thin layer may be larger in amount of the doped element than the remaining zinc oxide thin layer.

The above thin film transistor may further include a passivation layer formed on the active layer between the source electrode and the drain electrode.

The passivation layer may be formed in a single layer structure or in at least a two-layer structure, and at least some of the passivation layer may be formed by a chemical vapor deposition process which does not use plasma.

The passivation layer may include: a first passivation layer which is formed on the active layer by the chemical vapor deposition which does not the plasma; and a second passivation layer which is formed on the first passivation layer by the chemical vapor deposition which uses plasma.

In accordance with another exemplary embodiment, a method of manufacturing a thin film transistor includes: providing a substrate; forming a gate electrode on the substrate and forming a gate dielectric on the substrate including the gate electrode; forming an active layer on the gate dielectric; and forming source electrode and drain electrode on the active layer, wherein the active layer is formed of a doped ZnO thin layer and the doped ZnO thin layer is formed in at least a two-layer structure by a chemical vapor deposition process.

The above method may further include forming a passivation layer on the active layer to pattern the passivation layer such that the passivation layer is left between the source electrode and the drain electrode.

The ZnO thin layer may be doped with at least one of gallium, indium and tin.

The doped ZnO thin layer may include at least one of an IGZO thin layer and an ITZO thin layer having a multilayer structure comprising at least two layers stacked.

The doped at least two ZnO thin layers may include a first zinc oxide thin layer formed by an ALD process, and a remaining layer formed by at least one of a pseudo A/D process, a cyclic CVD process and a CVD process.

The first zinc oxide thin layer of the doped at least two ZnO thin layer may be formed by the ALD process and a second layer may be formed by the CVD process.

The first zinc oxide thin layer of the doped at least two ZnO thin layers may be formed by the ALD process and a second layer may be formed by the cyclic CVD process.

The first zinc oxide thin layer of the doped at least two ZnO thin layers may be formed by the ALD process; a second layer may be formed by the pseudo ALD process; and a third layer is formed by the CND process.

The first zinc oxide thin layer of the doped at least two ZnO thin layer may be formed by the ALD process, a second layer may be formed by the cyclic CVD process, and a third layer may be formed by the CVD process.

The doped at least two ZnO thin layers may be formed with different composition ratios by controlling an introduced amount of a deposition source.

The first zinc oxide thin layer may be larger in amount of the doped element than the remaining layer, and the first zinc oxide thin layer may be higher in mobility and conductivity than the remaining layer.

The passivation layer may be formed in a single layer structure or in at east a two-layer structure.

The passivation layer may include a first passivation layer contacting the active layer, and a remaining second passivation layer, and the first passivation layer may be formed by the chemical vapor deposition which does not plasma, and the second passivation layer may be formed by a chemical vapor deposition which uses plasma.

The first passivation layer may be formed by using a silicon source and a first reaction source, and the second passivation layer may be formed by using the silicon source and a second reaction source.

The silicon source may include TEOS and SiH₄, the first reaction source may include O₃, and the second reaction source may include O₂, N₂O, and NH₃.

The first passivation layer may be formed by using TEOS and O₃.

The second passivation layer may be formed by using TEOS or SiH₄ and O₂, N₂O or NH₃.

The above method may, at least one of before and after the forming of the passivation layer, further include performing an annealing process.

The forming of the gate dielectric, the forming of the active layer and the forming of the passivation layer and the annealing may be performed in-situ.

### BRIEF DESCRIPTION OF THE DRAWINGS

Exemplary embodiments can be understood in more detail from the following description taken in conjunction with the accompanying drawings, in which:

FIG. 1 is a cross-sectional view of a thin film transistor in accordance with an exemplary embodiment;

FIGS. 2 and 3 are characteristic graphs of a thin film transistor in accordance with an exemplary embodiment;

FIGS. 4 through 6 are cross-sectional views of thin film transistors in accordance with other exemplary embodiments;

FIGS. 7 through 11 are characteristic graphs of IGZO thin layers formed by various processes;

FIGS. 12 through 14 are schematic views of a deposition apparatus employed in manufacturing a thin film transistor in accordance with an exemplary embodiment;

FIGS. 15 through 17 are schematic views of process cycles in an ALD process, a pseudo ALD process and a CVD process applied to exemplary embodiments;

FIGS. 18 through 21 are cross-sectional views sequentially illustrating a method of manufacturing a thin film transistor in accordance with an exemplary embodiment;

FIG. 22 is a process flow diagram for explaining a method of manufacturing a thin film transistor in accordance with another exemplary embodiment; and

FIGS. 23 through 26 are cross-sectional views sequentially illustrating a method of manufacturing a thin film transistor in accordance with another exemplary embodiment.

### DETAILED DESCRIPTION OF EMBODIMENTS

Hereinafter, specific embodiments will be described in detail with reference to the accompanying drawings.

The present invention may, however, be embodied in different forms and should not be construed as limited to the embodiments set forth herein. Rather, these embodiments are provided so that this disclosure will be thorough and complete, and will fully convey the scope of the present invention to those skilled in the art. In figures, the dimensions of layers and regions are exaggerated for clarity of illustration. Like reference numerals refer to like elements throughout. It will also be understood that when a layer, a film, a region or a plate is referred to as being ‘on’ another one, it can be directly on the other one, or one or more intervening layers, films, regions or plates may also be present.

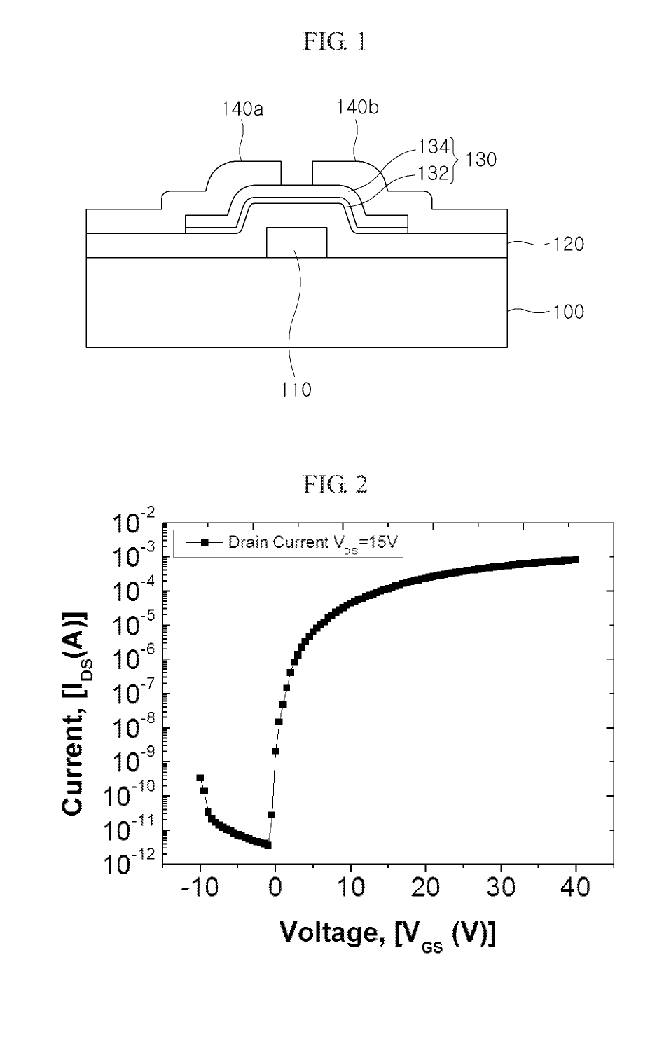

FIG. 1 is a cross-sectional view of a thin film transistor, e.g., a bottom gate type thin film transistor in accordance with an exemplary embodiment.

Referring to FIG. 1, a thin film transistor in accordance with an exemplary embodiment includes a gate electrode 110 formed on a substrate 100, a gate dielectric 120 formed on the gate electrode 110, a two layer-structured active layer 130 formed on the gate dielectric of a ZnO thin layer doped with Group III or IV elements, and source electrode 140a and drain electrode 140b formed on the active layer 130 and spaced apart from each other.

The substrate 100 may be a transparent substrate, such as a silicon substrate, a glass substrate or a plastic substrate (e.g., PE, PES, PET, PEN, etc.) for a flexible display. Alternatively, the substrate 100 may be a reflective substrate, such as a metal substrate. The metal substrate may be formed of stainless steel, titanium (Ti), molybdenum (Mo), or alloys thereof. Meanwhile, in the case where the substrate 100 is a metal substrate, an insulation layer may be formed on the metal substrate. The forming of the insulation layer is to prevent the metal substrate from being shorted with the gate electrode 110 and also to prevent metal atoms from being diffused from the metal substrate. The insulation layer may be formed of a material including at least one of silicon oxide (SiO₂), silicon nitride (SiN), alumina (Al₂O₃), and compounds thereof. In addition, a diffusion stop layer may be formed of an inorganic material including at least one of titanium nitride (TiN), titanium aluminum nitride (TiAlN), silicon carbide (SiC), and compounds thereof under the insulation layer.

The gate electrode 110 may be formed of a conductive material, for example, aluminum (Al), neodymium (Nd), silver (Ag), chromium (Cr), titanium (Ti), tantalum (Ta), molybdenum (Mo), copper (Cu), or alloys thereof. Also, the gate electrode 110 may be formed in a multilayer structure having a plurality of metal layers as well as a single layer structure. For example, the gate electrode 110 may be formed in a two-layer structure comprised of a metal layer of Cr, Ti, Ta, Mo, or the like having superior physical and chemical characteristics, and another Al-based, Ag-based, or Cu-based metal layer having a low resistivity.

The gate dielectric 120 is formed at least on the gate electrode 110. That is, the gate dielectric 120 may be formed on the substrate 100 including an upper surface and side surfaces of the gate electrode 110. The gate dielectric 120 may be formed of one of inorganic dielectrics having superior adhesivity to a metallic material and including silicon oxide (SiO₂), silicon nitride (SiN), alumina (Al₂O₃), zirconia (ZrO₂), or the like, or a dielectric other than the foregoing inorganic dielectrics.

The active layer 130 is formed on the gate dielectric 120 such that at least some of the active layer 130 overlaps the gate electrode 110. The active layer 130 may be induced into an amorphous ZnO thin layer so as to improve the film quality of the ZnO thin layer by doping a Group III or IV element, for example, at least one of indium (In), gallium (Ga), and tin (Sn), into a ZnO thin layer, thereby improving the stability of the thin film transistor. For example, the active layer 130 may be formed of an IGZO thin layer obtained by doping In and Ga into a ZnO thin layer, or formed of an ITZO thin layer obtained by doping In and Sn into a ZnO thin layer. The following embodiments will be described with an example of the IGZO thin layer. Also, in the active layer 130 formed of IGZO thin layer, the active layer of a thickness is formed by an ALD process, and the IGZO thin layer of the remaining thickness is formed by a chemical vapor deposition (CVD) process, a cyclic CVD process, or the like. For example, the active layer 130 may be formed at least in a two-layer structure, in which a first IGZO thin layer 132 adjacent to the gate dielectric 120 is formed by an ALD process and a second IGZO thin layer 134 is formed on the first IGZO thin layer 132 by a CVD process or a cyclic CVD process. Herein, the ALD process is performed by repeating the supplying of a raw material source and purging and the supplying of an oxidation source and purging, and the CVD process is performed by simultaneously supplying a raw material source and an oxidation source. In the case of the raw material source, a process is performed a raw material gas supplying a raw material, and in the case of the oxidation source, a process is performed with a reaction gas that may react with a raw material gas to form a desired thin layer. Also, the cyclic CVD process is performed by repeating supply and stop of a raw material source and continuously supplying an oxidation source. Also, the cyclic CVD process is performed by repeating supply and stop of a raw material source and continuously supplying an oxidation source. Therefore, the CND process may enhance the process speed, and the cyclic CND process may allow the film quality to be dense since a raw material source and an oxidation source are simultaneously supplied so that a simultaneous deposition is performed, and an oxidation source supplied later reacts with the raw material source. A process in which supply and stop of a raw material source are repeated and an oxidation source is continuously supplied is continuously performed for one period, and then a process including a step of stopping supply of the oxidation source for a few seconds is performed. There is a difference between the cyclic CVD process and the ALD process. In the ALD process, a purge step is performed after supply of a raw material source or oxidation source is stopped, whereas in the cyclic CVD process, a separate purge step is not performed while a process is performed, and a process in which a cycle is repeated several times is performed. Meanwhile, the first and second IGZO thin layers 132 and 134 may be formed using an indium source, a gallium source, a zinc source, and an oxidation source. For example, Tirmethyl Indium (In(CH₃)₃; TMIn), Diethylamino propyl Dimethyl indium (DADI), or the like may be used as the indium source, Trimethyl Gallium (Ga(CH₃)₃; TMGa) or the like may be used as the gallium source, and Diethyl Zinc (Zn(C₂H₅)₂; DEZ), Dimethyl Zinc (Zn(CH₃)₂; DMZ) or the like may be used as the zinc source. Also, an oxygen-containing material, for example, at least one of oxygen (O₂), ozone (O₃), vapor (H₂O), N₂O, CO₂, and the like may be used as the oxidation source. In the active layer 130, the first IGZO thin layer 132 adjacent to the gate dielectric 120 may be formed by an ALD process and used as a front channel. Since the first IGZO thin layer 132 formed by the ALD process is superior in film quality and interfacial characteristic, the first IGZO thin layer 132 may be used as a front channel which is important in forming a channel. That is, when a voltage is applied to the gate electrode 110, negative (−) charges are accumulated in a portion of the active layer 130 on the gate dielectric 120 to form a front channel. As current flows well through the front channel, the mobility is superior. Therefore, it is preferable that the front channel region should be formed of a material having superior mobility. Since the first IGZO thin layer 132 formed by the ALD process is superior in film quality and interfacial characteristic, the mobility is superior too. Then, since the ALD process lowers productivity due to slow speed thereof, the second IGZO thin layer 134 on the first IGZO thin layer 132 is formed by a CVD process or cyclic CVD process. Since the CVD process or cyclic CVD process makes it possible to deposit a film at a high speed, productivity can be enhanced. Meanwhile, while an oxygen-containing material may be used as the oxidation source of the ALD process, when oxygen (O₂) is used as a reaction gas, TMGa has low reactivity. Thus, it is preferable to use ozone (O₃) as the oxidation source. In the case that oxygen (O₂) is used as the oxidation source, oxygen is excited into a plasma state. In addition to oxygen (O₂), N₂O and CO₂ may be also excited into a plasma state and used. Also, oxygen, ozone, a mixture of vapor and oxygen, a mixture of vapor and ozone, oxygen plasma or the like may be used as the oxidation source of the CVD process or cyclic CVD process, and preferably, the mixture of vapor and oxygen, or the mixture of vapor and ozone is used. Meanwhile, the second IGZO thin layer 134 may be formed with a composition ratio different from that of the first IGZO thin layer 132 to be used as the back channel. That is, when a negative (−) voltage is applied to the gate electrode 110, negative (−) charges are accumulated in a portion of the active layer 130 under the source electrode 140a and the drain electrode 140b. Therefore, the second IGZO thin layer 134 is formed as the back channel such that the second IGZO thin layer 134 has a conductivity lower than the first IGZO thin layer 132 functioning as the front channel. For this purpose, the introduced amount of at least one of indium source and gallium source may be controlled differently from that for the forming of the first IGZO thin layer 132, and the introduced amount of oxidation source may be also controlled. For example, the compositions of indium and gallium in the second IGZO thin layer 134 may be made less than those in the first IGZO thin layer 132. By doing so, characteristics of the first IGZO thin layer 132 and the second IGZO thin layer 134, for example, mobility, electrical conductivity, etc. may be controlled. The first IGZO thin layer 132 may be formed in a thickness range of approximately 5 Å to approximately 50 Å, and the second IGZO thin layer 134 may be formed in a thickness range of approximately 200 Å to approximately 300 Å. If the first and second IGZO thin layers 132 and 134 are formed thinner or thicker than the foregoing thickness range, the mobility between the source electrode 140a and the drain electrode 140b is lowered and thus operation characteristics of the thin film transistor become poor.

The source electrode 140a and the drain electrode 140b are formed on the active layer 130, and are space apart from each other with the gate electrode 110 in between while partially overlapping the gate electrode 110. The source electrode 140a and the drain electrode 140b may be formed by the same process using the same material. For example, the source electrode 140a and the drain electrode 140b may be formed of a conductive material, for example, at least one of aluminum (Al), neodymium (Nd), silver (Ag), chromium (Cr), titanium (Ti), tantalum (Ta), molybdenum (Mo), copper (Cu), and alloys thereof. That is, the source electrode 140a and the drain electrode 140b may be formed of a material which is the same as the gate electrode 110, but may be formed of a material which is different from the gate electrode 110. Also, the source electrode 140a and the drain electrode 140b may be formed in a multilayer structure having a plurality of metal layers as well as in a single layer structure.

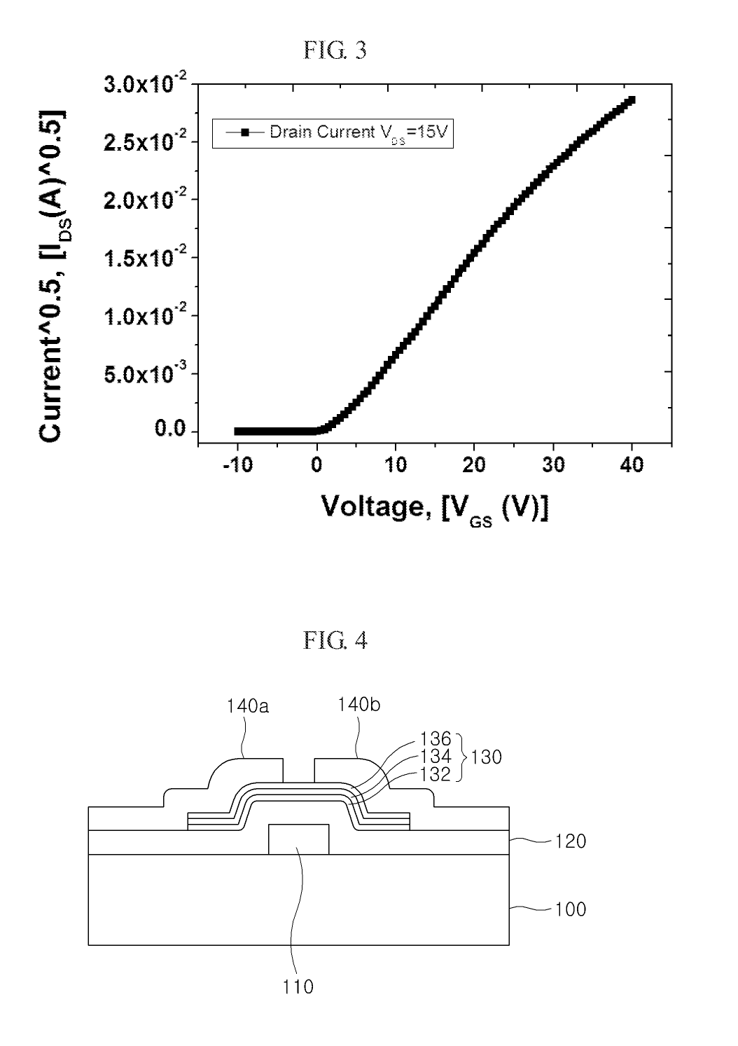

FIGS. 2 and 3 are characteristic graphs of a thin film transistor which uses an IGZO thin layer in accordance with an exemplary embodiment as an active layer, particularly, FIG. 2 is a drain-source current (IDS) graph according to a gate voltage, and FIG. 3 shows that the drain-source current (IDS) on the Y-axis of FIG. 2 is expressed by index. As illustrated in the figures, when the gate voltage applied is 0 V or more, tunneling occurs between drain electrode and source electrode and thus a drain-source current flows to show a linear characteristic. Also, when the gate voltage applied is a predetermined voltage, for example, 10 V or more, the drain source current is saturated. This characteristic graph is similar to that of a thin film transistor having an IGZO thin layer formed by sputtering. Thus, it can be seen that the thin film transistor having the IGZO thin layer which is formed by a chemical vapor deposition process and is used as an active layer operates normally.

As described above, in the case of the thin film transistor according to an exemplary embodiment of the disclosure, the active layer 130 is formed of a metal oxide semiconductor, particularly an IGZO thin layer, in a stack structure having the first IGZO thin layer 132 and the second IGZO thin layer 134 formed by the ALD process and the CVD process or the ALD process and the cyclic CVD process. At this time, since it is possible to control the compositions of the first and second IGZO thin layers 132 and 134 through control of the introduced amount of source, the multilayer structured active layer 130 each layer having a different composition can be formed. Also, since the first IGZO thin layer 132 may be formed by the ALD process capable of Obtaining superior film quality and used as a front channel, a high speed device having superior mobility and electrical conductivity can be realized, and since the second IGZO thin layer 134 may be formed by the CND process or cyclic CVD process capable of performing a high speed deposition and used as a front channel, productivity reduction, which is a disadvantage of the ALD process can be compensated. That is, in the case the IGZO thin layer is formed only by the ALD process which is slow in process speed, productivity is lowered, and in the case the IGZO thin layer is formed only by the CVD process which is fast in process speed, the film quality of the IGZO thin layer is lowered and thus device operation reliability cannot be guaranteed. However, since the ALD process and the CND process or the ALD process and the cyclic CVD process are used, the foregoing problem can be solved.

FIG. 4 is a cross-sectional view of a thin film transistor in accordance with another exemplary embodiment in which an active layer using an IGZO thin layer is formed with three layers by different deposition processes.

Referring to FIG. 4, a thin film transistor in accordance with another exemplary embodiment includes a gate electrode 110 formed on a substrate 100, a gate dielectric 120 formed on the gate electrode 110, an active layer formed in three layers on the gate dielectric 120, and a source electrode 140a and drain electrode 140b spaced apart from each other on the active layer 130.

The active layer 130 is formed by stacking a first IGZO thin layer 132, a second IGZO thin layer 134 and a third IGZO thin layer 136. For example, the first IGZO thin layer 132 may be formed by an ALD process, the second IGZO thin layer 134 may be formed by a pseudo ALD process, and the third IGZO thin layer 136 may be formed by a CVD process. Also, the first IGZO thin layer 132 may be formed by an ALD process, the second IGZO thin layer 134 may be formed by a cyclic CVD process, and the third IGZO thin layer 136 may be formed by a CVD process. That is, the first and third IGZO thin layers 132 and 136 may be formed by an ALD process and a CVD process, respectively, and the second IGZO thin layer 134 may be formed by a pseudo ALD process or a cyclic CVD process. Herein, the pseudo ALD process forms a thin layer having a predetermined thickness by repeating the introduction of a raw material source and introduction of an oxidation source. That is, while the ALD process forms a thin layer by repeating the introduction and purge of a raw material source and the introduction and purge of an oxidation source, the pseudo ALB process forms a thin layer by repeating introduction of a raw material source and introduction of an oxidation source without a purge process. Also, the pseudo ALD process may use the oxidation source used in the ALD process as an oxidation source. That is, an oxygen-containing material, preferably ozone (O3), may be used as the oxidation source, and oxygen (O₂), N₂O and CO₂ may be also used after being excited to a plasma state. When the active layer 130 is formed in the three-layer structure as above, the film quality of the active layer 130 can be further improved compared with the IGZO thin layer formed in the two-layer structure by the ALD process and the CVD process because the second IGZO thin layer 134 formed by the pseudo ALD process or cyclic CVD process has a film quality similar to the first IGZO thin layer 132 formed by the ALD process and can be deposited at a higher speed than the second IGZO thin layer formed by the ALD. Meanwhile, the first IGZO thin layer 132 may be formed with a thickness ranging from approximately 10 Å to approximately 50 Å, the second IGZO thin layer 134 may be formed with a thickness ranging from approximately 50 Å to approximately 100 Å, and the third IGZO thin layer 136 may be formed with a thickness ranging from approximately 150 Å to approximately 250 Å.

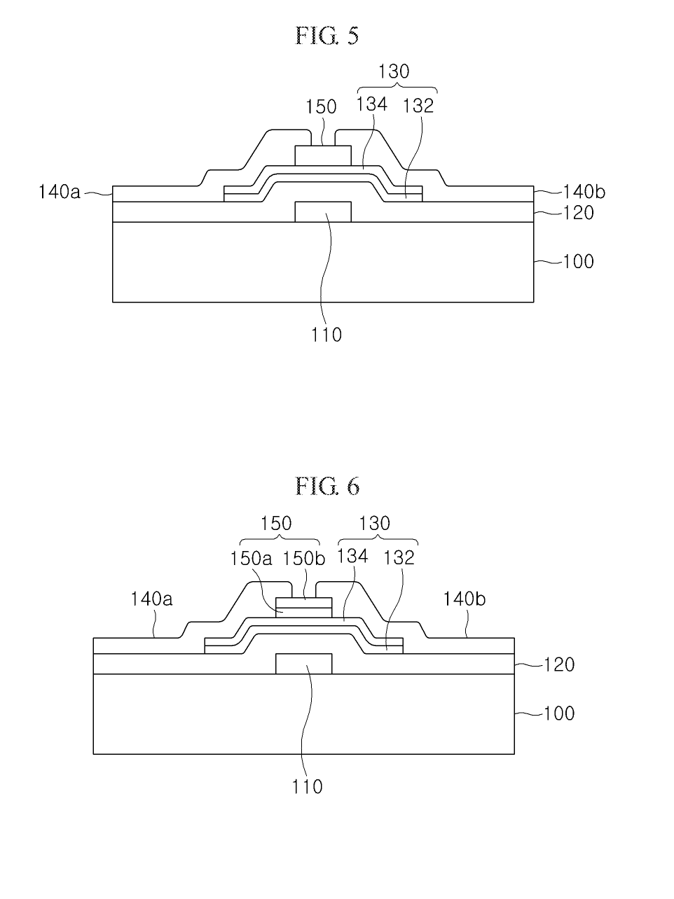

Meanwhile, if the active layer 130 formed of an IGZO thin layer is exposed to the atmosphere when the source electrode 140a and the drain electrode 140b are formed thereon, moisture, oxygen, etc. may penetrate to cause oxygen defects, so that excess carriers may be generated to increase off-current or change the threshold voltage. Therefore, a passivation layer 150 is formed on the active layer 130 so as to prevent oxygen from penetrating into the active layer 130, as illustrated in FIG. 5.

Referring to FIG. 5, a thin film transistor in accordance with another exemplary embodiment includes a gate electrode 110 formed on a substrate 100, a gate dielectric 120 formed on the gate electrode 110, an active layer formed on the gate dielectric 120 and having at least a two-layer structure, source electrode 140a and drain electrode 140b spaced apart from each other on the active layer 130, and the passivation layer formed on the active layer 130 between the source electrode 140a and the drain electrode 140b.

The passivation layer 150 is formed so as to function as an etch stop layer in an etch process for ung the source electrode 140a and the drain electrode 140b after the active layer 130 is formed, and to thus prevent the active layer 130 from being exposed and damaged. Also, the passivation layer 150 may prevent the active layer 130 from being exposed to the atmosphere after the source electrode 140a and 140b are formed. That is, if the first and second IGZO thin layers 132 and 134 are exposed to atmosphere, characteristics of the first and second IGZO thin layers 132 and 134 may be degraded due to penetration of moisture, oxygen and the like. Therefore, the passivation layer 150 may be formed to prevent penetration of moisture, oxygen and the like. The passivation layer 150 may be formed of a material which can prevent moisture and oxygen from penetrating and has a different etch selectivity from the active layer 130 during the etch process. For example, the passivation layer 150 may be formed of an insulation material such as silicon oxide (SiO₂), silicon oxynitride (SiON), or the like in a single layer structure or a multilayer structure. Also, at least some of the passivation layer 150 may be formed by using a CVD process. That is, in the case of forming the passivation layer 150 by using plasma, the active layer 130 may be damaged by plasma. Therefore, a portion of the passivation layer 140 contacting the active layer 130 is formed by a CVD process.

Also, the passivation layer 150 may be formed in a multilayer structure, for example, in a two-layer structure having a first passivation layer 150a and a second passivation layer 150b, as illustrated in FIG. 6. At this time, the first and second passivation layers 150a and 150b may be formed by different deposition processes. That is, the first passivation layer 150a may be formed by a CVD process and the second passivation layer 150b may be formed by a PECVD process. That is, in the case of forming the passivation layer 150 using plasma, the film quality of the passivation layer 150 may be improved but the active layer 130 may be damaged by plasma. Therefore, the first passivation layer 150a is formed by a CVD process and the second passivation layer 150b is formed by a PECVD process. Also, the first passivation layer 150a may be formed by an ALD process. Meanwhile, in the case where the passivation layer 150 is formed in a multilayer structure, source gas and reaction gas for forming the first passivation layer 150a may be different from those for forming the second passivation layer 150b. For example, when the passivation layer 150 is formed of silicon oxide in a two-layer structure, the first passivation layer 150a uses TEOS as a source gas and O3 as a reaction gas, and the second passivation layer 150b uses TEOS as a source gas and O₂, N₂O or NH₃ as a reaction gas. Alternatively, the first passivation 150a may use TEOS as a source gas and the second passivation layer 150b uses SiH₄ as a source gas. In addition, the first and second passivation layers 150a acrd 150b may be formed of different materials. For example, the first passivation layer 150a may be formed of silicon oxide and the second passivation layer 150b may be formed of silicon oxynitride. Also, the passivation layer 150 having a multilayer structure may be formed at different deposition temperatures. The first and second passivation layers 150a and 150b may be formed in a temperature range, for example, at the same temperature, or at different temperatures.

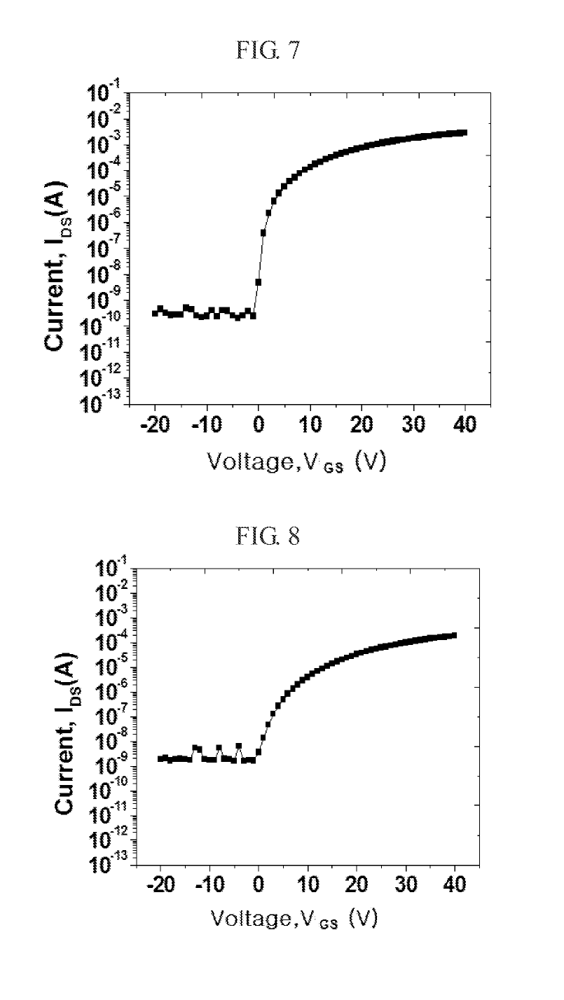

FIGS. 7 through 11 are graphs for comparing operation characteristic of IGZO thin layers formed by various processes and used as an active layer.

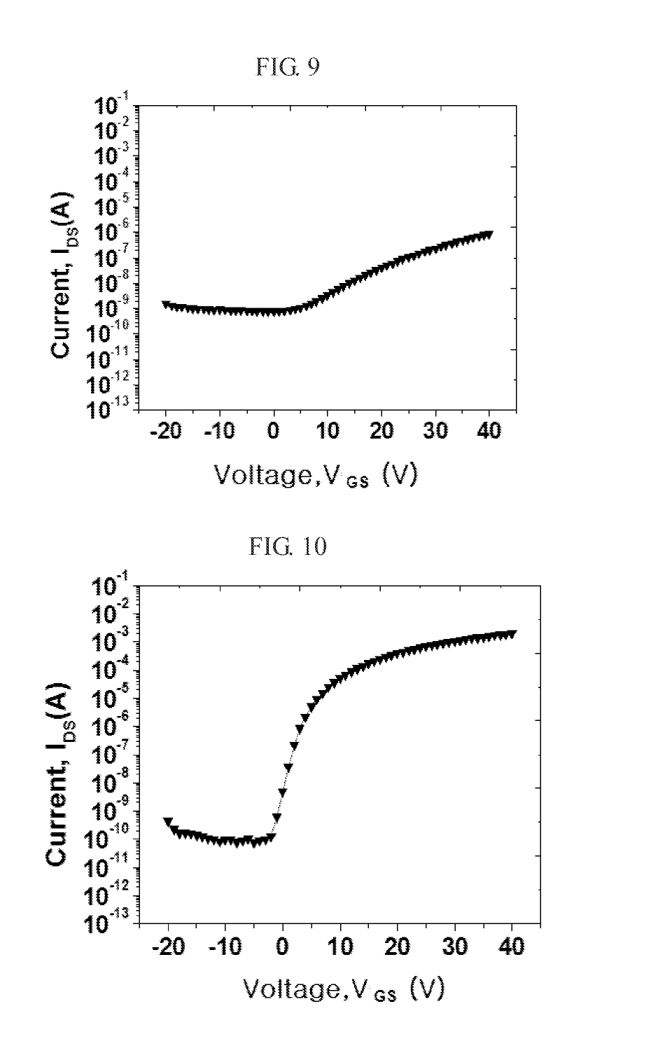

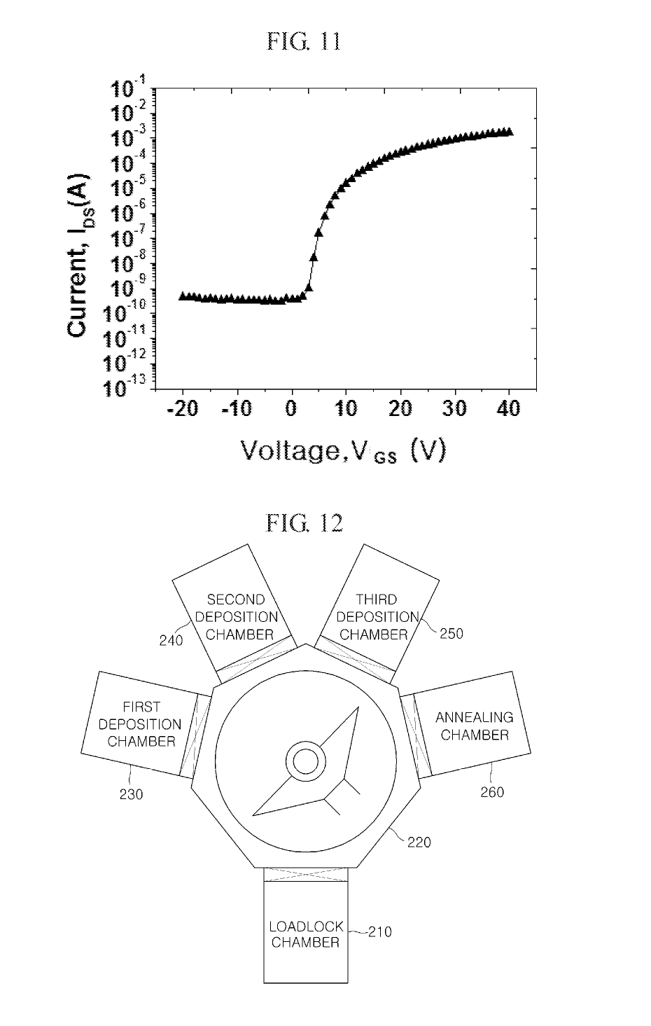

FIG. 7 is a characteristic graph of an IGZO thin layer formed by only an ALD process, in which mobility is 19.2, threshold voltage is 4.26 V and slop swing is 0.524. Herein, slop swing indicates that as the value approaches zero (0), the characteristic graph approaches a vertical profile and thus charge transfer speed is high. FIG. 8 is a characteristic graph of an IGZO thin layer formed by only a CVD process, in which mobility is 0.9, threshold voltage is 5.54V and slop swing is 1.8. In the case of the IGZO thin layer illustrated in FIG. 8, since the mobility is 0.9 which is a very low value, device operation is almost impossible. FIG. 9 is a characteristic graph of a device having an IGZO thin layer formed by only a CVD process, in which since the device having the IGZO thin layer formed by only a CVD process does not operate, no characteristic can be measured. Meanwhile, FIG. 10 is a characteristic graph of a device having a first IGZO thin layer formed by an ALD process and a second IGZO thin layer formed by a cyclic CVD process, in which mobility is 13.1, threshold voltage is 7.01 V, and slop swing is 1.31. In the case where the ALD process and the cyclic CVD process are used as above, since the characteristic graph follows the characteristic graph of the device having the IGZO thin layer formed by only an ALD and the mobility is superior, high speed operation becomes possible. FIG. 11 is a characteristic graph of a device having a first IGZO thin layer formed by an ALD process, a second IGZO thin layer formed by a cyclic CVD process, and a third IGZO thin layer formed by a CVD process, in which mobility is 12.1, threshold voltage is 7.01 and slop swing is 1.31. Since the characteristic of FIG. 11 follows the characteristic graph of the device having the IGZO thin layer formed by only the ALD process and the mobility is superior, high speed operation becomes possible.

That is, the IGZO formed by the ALD process is superior in its characteristics but is slow in deposition rate, so that productivity is low, whereas the IGZO thin layer formed by the cyclic CVD process or the CVD process is fast in deposition rate but has unfavorable characteristics. However, in the case of forming a first IGZO thin layer by an ALD process and then forming a second IGZO thin layer by a cyclic CVD process, or in the case of forming a third IGZO thin layer on the second IGZO thin layer by a CVD process, a difference in film quality at interfaces between the thin layers is not great and thus the IGZO thin layer quality is not lowered. That is, the IGZO thin layer formed in a multilayer structure by different processes may have a superior film quality which is a characteristic of the ALD process and a fast deposition rate which is a characteristic of the cyclic CVD or CVD process. Therefore, productivity can be enhanced and the operation characteristic can be maintained.

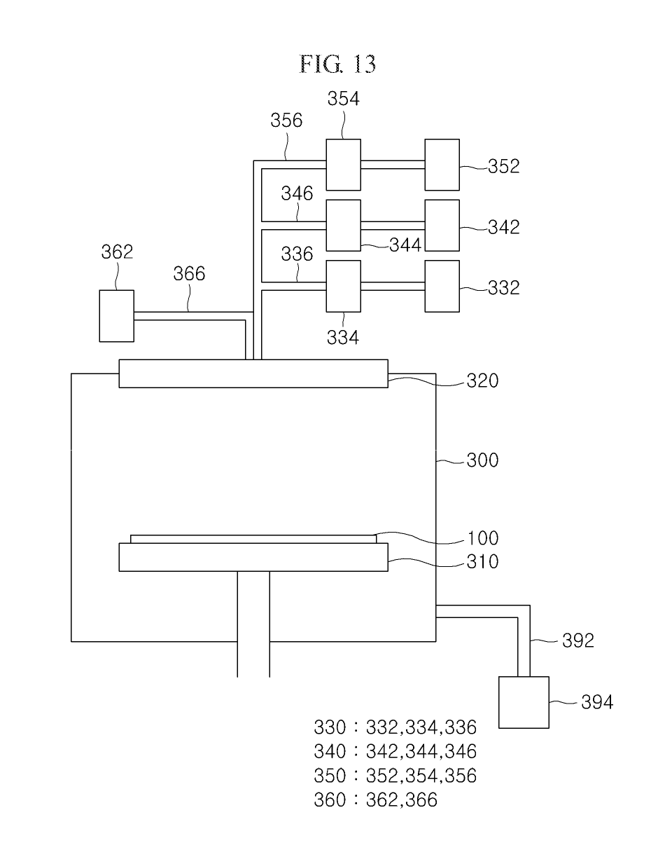

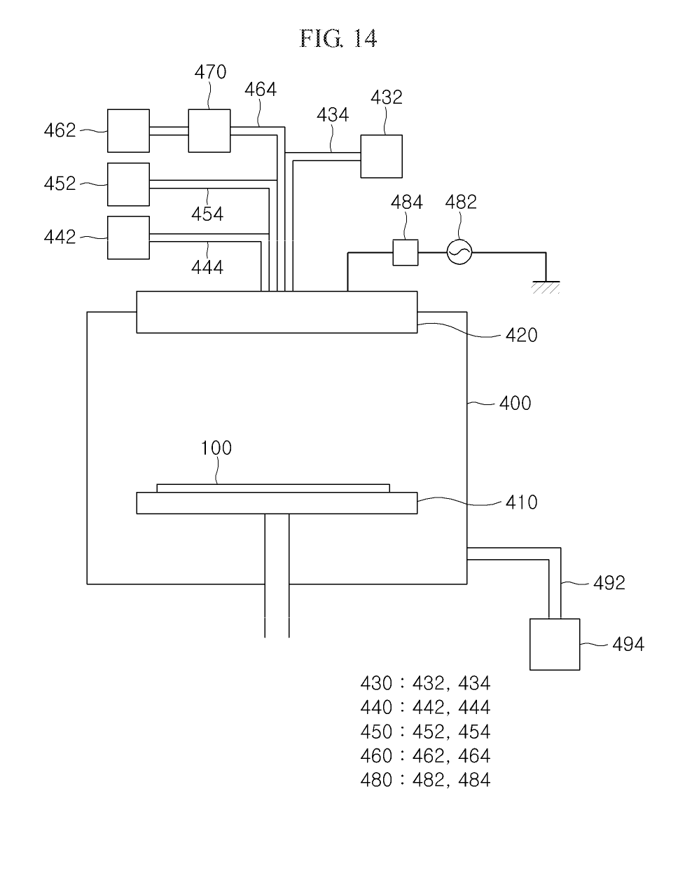

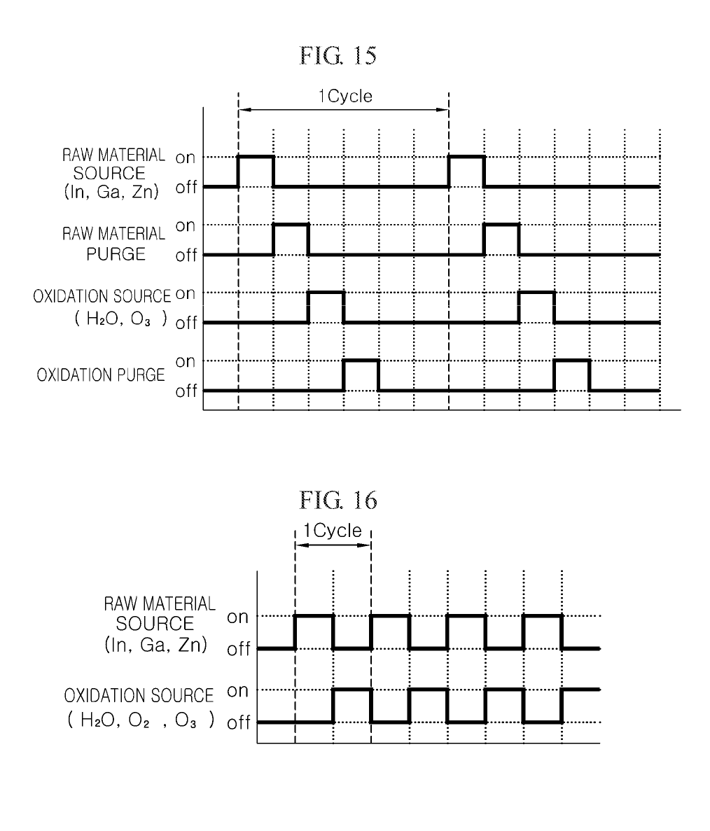

FIG. 12 is a schematic view of a process apparatus for manufacturing a thin film transistor in accordance with an exemplary embodiment, i.e., of a cluster including a plurality of deposition chambers. FIG. 13 is a schematic view of a deposition apparatus for forming an active layer of a thin film transistor in accordance with an exemplary embodiment, in which the deposition apparatus is used to form a plurality of IGZO thin layers in-situ by simultaneously performing an ALD process and a pseudo CVD process or an ALD process and a cyclic CVD process or further performing a CVD process. FIG. 14 is a schematic view of a deposition apparatus for forming a passivation layer of a thin film transistor in accordance with an exemplary embodiment, in which a CVD process and a PECVD process can be performed simultaneously. FIGS. 15 through 17 are schematic views of process cycles in an ALD process, a pseudo ALD process and a CVD process applied to exemplary embodiments.

As illustrated in FIG. 2, a process apparatus used in the present disclosure includes at least one loadlock chamber 210, a transfer chamber 220, a plurality of deposition chambers 230, 240 and 250, and an annealing chamber 260. Herein, the first deposition chamber 230 may be a chamber for depositing a gate dielectric, the second deposition chamber 240 may be a chamber for forming an active layer including at least one IGZO thin layer, and the third deposition chamber 250 may be a chamber for forming at least one passivation layer. Also, the annealing chamber 260 is a chamber for annealing a substrate at least one time after forming of a passivation layer, after the forming of the passivation layer, or before and after the forming of the passivation layer. Therefore, it is possible to perform deposition of the gate dielectric, deposition of the active layer, and depostion and annealing of the passivation layer in-situ while maintaining the process apparatus in a vacuum state.

Also, as illustrated in FIG. 13, a deposition apparatus for forming an active layer including a plurality of IGZO thin layers of a thin film transistor in accordance with an exemplary embodiment includes a reaction chamber 300 provided with a predetermined reaction space, a susceptor 310 disposed at an inner lower portion of the reaction chamber 300, a gas distribution plate 320 disposed at an inner upper portion of the reaction chamber 300 to correspond to the susceptor 310, a first source supply part 330 for supplying an indium source, a second source supply part 340 for supplying a gallium source, a third source supply part 350 for supplying a zinc source, and a fourth source supply part 360 for supplying an oxidation source. Also, although not illustrated in the drawing, the deposition apparatus further includes a purge gas supply part for supplying a purge gas such as inert gases. The first, second and third source supply parts 330, 340 and 350 may include source storage parts 332, 342 and 352, bubblers 334, 344 and 354 vaporizing a source material to genrate a source gas, and supply tubes 336, 346 and 356 supplying the vaporized source material to the reaction chamber 300. Also, the fourth source supply part 360 supplying the oxidation source includes a source storage part 362 storing an oxidation source, and a supply tube 366 supplying the oxidation source to the reaction chamber 300. In the case H₂O or the like is used as the oxidation source, the fourth source supply part 360 may further include a bubbler. Although not illustrated in the drawing, a control means (not shown) such as a valve controlling a supply or supply amount of a source may be installed on the supply tubes 336, 346, 356 and 366. Also, the deposition apparatus may further include a vacuum line 392 and a vacuum pump 394 for controlling inner pressure of the reaction chamber 300 and maintaining the reaction chamber in a vacuum state. Meanwhile, the susceptor 310 may be provided therein with a heater (not shown) and a cooling means (not shown) to maintain the substrate 100 at a desired temperature. Herein, a gate electrode, a gate dielectric and the like may be formed on the substrate 100, and at least one substrate 100 may be mounted on the susceptor 310.

To form an IGZO thin layer by an AM process using the foregoing deposition apparatus, as illustrated in FIG. 15, an indium source, a gallium source and a zinc source are simultaneously supplied into the reaction chamber 300 through the first, second and third source supply parts 330, 340 and 350 to adsorb the raw material sources on the substrate 100. Thereafter, the supply of the raw material sources is stopped and a purge gas such as an inert gas or the like is supplied to purge the raw material sources which are not adsorbed. Thereafter, an oxidation source is supplied into the reaction chamber 300 through the fourth source supply part 360 to react the raw material source ads bed on the substrate 100 with the oxidation source, thereby forming IGZO thin layer in an atomic layer form. Thereafter, the supply of the oxidation source is stopped and then a purge gas such as an inert gas is supplied into the reaction chamber 300 to purge source gases which are not reacted. A cycle including supply and purge of the raw material sources and supply and purge of the oxidation source is repeated at least two times to form an IGZO thin layer having a predetermined thickness.

To form an IGZO thin layer by a pseudo ALD process using the foregoing deposition apparatus, as illustrated in FIG. 16, an indium source, a gallium source and a zinc source are simultaneously supplied into the reaction chamber 300 through the first, second and third source supply parts 330, 340 and 350 to adsorb the raw material sources on the substrate 100. Thereafter, an oxidation source is supplied into the reaction chamber 300 through the fourth source supply part 360 to react the raw material source adsorbed on the substrate 100 with the oxidation source, thereby forming an IGZO thin layer in an atomic layer form. A cycle including a supply of the raw material sources and supply of the oxidation source is repeated at least two times to form an IGZO thin layer having a predetermined thickness.

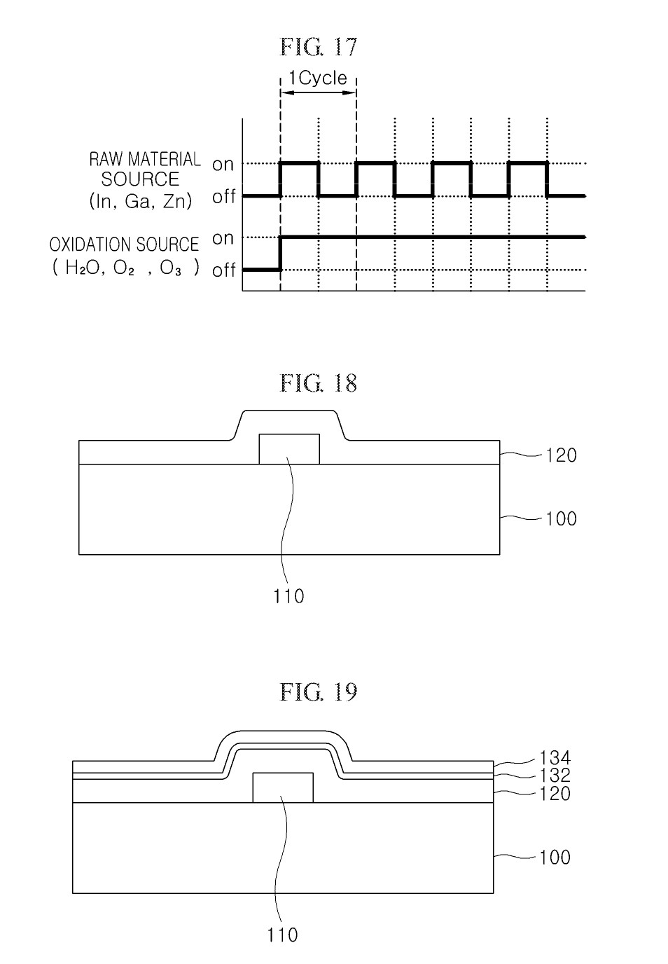

To form an IGZO thin layer by a cyclic CVD process using the foregoing deposition apparatus, as illustrated iii FIG. 17, an indium source, a gallium source and a zinc source are simultaneously supplied into the reaction chamber 300 through the first, second and third source supply parts 330, 340 and 350 and at the same time an oxidation source is supplied into the reaction chamber 300 through the fourth source supply part 360. The supply of the oxidation source is maintained even when the raw material sources are stopped through the first, second and third source supply parts 330, 340 and 350 and are again supplied. That is, the supply and stop of the raw material sources through the first, second and third source supply parts 330, 340 and 350 are repeated, and the supply of the oxidation source through the fourth source supply part 360 continues to be maintained. By doing so, an IGZO thin layer is formed on the substrate 100 by reaction of such sources. In the case the cyclic CVD process is used, since the raw material sources and the oxidation source are deposited at the same time on the substrate and the oxidation source, which is supplied later, reacts with the raw material sources, the IGZO thin layer becomes dense. By repeating the supply and stop of the raw material sources while maintaining the supply of the oxidation source, the IGZO thin layer is formed at a predetermined thickness.

Also, to form an IGZO thin layer by a CVD process using the foregoing deposition apparatus, an indium source, a gallium source and a zinc source are supplied into the reaction chamber 300 through the first, second and third source supply parts 330, 340 and 350 and at the same time an oxidation source is supplied into the reaction chamber 300 through the fourth source supply part 360.

Meanwhile, to form IGZO thin layer in accordance with the present disclosure in at least a two-layer structure by other deposition processes, various deposition apparatuses as well as the foregoing deposition apparatus may be used. For example, an IGZO thin layer having at least a two-layer structure may be formed in-situ by an ALD process, a CVD process and a pseudo ALD process by mounting a plurality of substrates 100 on a susceptor 310 and by using a rotational injection unit including a plurality of rotatable injectors and a unit rotating the susceptor 310. Of course, the IGZO thin layer having at least a two-layer structure may be formed ex-situ in another reaction chamber.

Also, as illustrated in FIG. 14, a deposition apparatus for forming a passivation layer of a thin transistor in accordance with the present disclosure includes a reaction chamber 400 provided with a predetermined reaction space, a susceptor 410 disposed at an inner lower side of the reaction chamber 400 to mount a substrate 100 thereon, a gas distribution plate 420 disposed at an inner upper side of the reaction chamber 400 to correspond to the susceptor 410, a first supply part 430 for supplying a silicon source through the gas distribution plate 420, a second supply part 440 for supplying a first reaction source, a third supply part 450 for supplying a second reaction source, and a fourth supply part 460 for supplying a cleaning gas or purge gas. In addition, the passivation layer deposition apparatus further includes a remote plasma generating part 470 fir activating the cleaning gas at the outside of the reaction chamber 400, and a plasma generating part 480 connected with the gas distribution plate 420 to activate a process gas. Therefore, the gas distribution plate 420 is made of a conductive material, and the plasma generating part 480 may include an RF power 482 and a matching unit 484. Also, the first to fourth supply parts 430, 440, 450 and 460 include source storage parts 432, 442, 452 and 462 and source supply lines 434, 444, 454 and 464, respectively, and although not illustrated in the drawing, may include a flowmeter for controlling flow of source. The passivation layer deposition apparatus may further include a vacuum line 492 and a vacuum pump 494 for maintaining the inside of the reaction chamber 400 in a vacuum. Meanwhile, the first supply part 430 may store a silicon source such as TEOS, SiH₄, or the like, the second supply part 440 may store an oxidation source such as O₂, O₃, or the like, and the third supply part 450 may store a nitrogen-containing source such as N₂O, NH₃, or the like. Also, the fourth supply part 460 may store a cleaning gas such as NF₃ or the like, and a purge gas such as Ar or the like.

By using the passivation layer deposition apparatus, a passivation layer having a single layer structure or multilayer structure may be formed. For example, a passivation layer having a single layer structure may be formed by forming a silicon oxide layer by a CVD process using TEOS and O₃ without applying RF power. Also, a first silicon oxide layer may be formed by a CVD process using TEOS and O₃ without applying RF power, and then a second silicon oxide layer may be formed by a PECVD process using TEOS and O₂ while applying RF power. Further, a silicon oxide layer may be formed by a CVD process using TEOS and O₃ without applying RIP power, and then a silicon oxynitride layer may be formed by a PECVD process using N₂O or NH₃. That is, while the passivation layer is formed in a single layer structure or a multilayer structure, a portion contacting the active layer 130 may be formed of silicon oxide by a CVD process, and the remaining portion may be formed of silicon oxide, silicon nitride or silicon oxynitride by a PECVD process.

FIGS. 18 through 21 are cross-sectional views sequentially illustrating a method of manufacturing a thin film transistor in accordance with an exemplary embodiment.

Referring to FIG. 18, a gate electrode 110 is formed on a predetermined region of a substrate 100, and then a gate dielectric 120 is formed on the entire region the substrate 100 including the gate electrode 110. The gate electrode 110 may be formed by forming a first conductive layer, for example, through a CVD process on the substrate 100 and then patterning the first conductive layer through a photolithography process using a predetermined mask. Herein, the first conductive layer may be formed of any one of metal, metal alloy, metal oxide, a transparent conductive layer and compound thereof. Also, the first conductive layer may be formed in a multilayer structure in consideration of a conductive characteristic and a resistance characteristic. The gate dielectric 120 may be form on the entire region of the substrate 100 including the gate electrode 110, of an inorganic insulation material or organic insulation material including oxide and/or nitride.

Referring to FIG. 19, after the substrate 100 is loaded into the deposition apparatus illustrated in FIG. 13, the temperature of the susceptor 310 is controlled such that the temperature of the substrate 100 is maintained at approximately 300° C. or less, for example, at 100° C. to 300° C. Next, a first IGZO thin layer 132 is formed on the entire region of the substrate 100 including the gate dielectric 120. The first IGZO thin layer 132 is formed by an ALD process having the process cycle illustrated in FIG. 15. That is, an indium source, a gallium source and a zinc source are simultaneously supplied into the reaction chamber 300 and are adsorbed on the substrate 100, and the source gases which are not adsorbed are purged by using a purge gas. Thereafter, an oxidation source is supplied into the reaction chamber 300 to react the oxidation source with the sources adsorbed on the substrate 100, thereby forming an IGZO thin layer having an atomic layer structure, and then source gases which are not reacted are purged by using a purge gas. Herein, the indium source, the gallium source and the zinc source may be supplied in ratio of 3-10:1-5:1, for example, in amounts of 150-200 sccm, 50-100 sccm, and 20-50 sccm, respectively. By repeating this cycle, the first IGZO thin layer 132 comprised of a plurality of stacked atomic layers. Herein, an oxygen-containing material, preferably ozone (O3), may be used as the oxidation source for the ALD process, and oxygen (O₂), N₂O and CO₂ may also be used after being excited to a plasma state. Also, a second IGZO thin layer 134 is formed on the first IGZO thin layer 132 by a CVD process or cyclic CVD process. For the cyclic CVD process, the simultaneous supply and stop of the indium source, the gallium source and the zinc source are repeated and the oxidation source continues to be supplied as illustrated in FIG. 17. Herein, the indium source, the gallium source and the zinc source may be supplied in a ratio of 3-10:1-5:1, for example, in amounts of 150-200 sccm, 50-100 sccm, and 20-50 sccm, respectively. Also, oxygen, ozone, a mixture of vapor and oxygen, a mixture of vapor and ozone, oxygen plasma or the like may be used as the oxidation source of the cyclic CVD process, and preferably, the mixture of vapor and oxygen, or the mixture of vapor and ozone is used. Meanwhile, the second IGZO thin layer 134 formed may have a different composition ratio from the first IGZO thin layer 132 by controlling the introduced amount of any one of the indium source, the gallium source and the zinc source to be smaller than that in the case of the first IGZO thin layer 132. The introduced amount of the oxidation source may be also controlled. By doing so, characteristics of the second IGZO thin layer 134, for example, mobility, electrical conductivity, etc. may be controlled, differently from those of the first IGZO thin layer 132. The first IGZO thin layer 132 may be formed in a thickness range of approximately 5 Å to approximately 50 Å, and the second IGZO thin layer 134 may be formed in a thickness range of approximately 200 Å to approximately 300 Å.

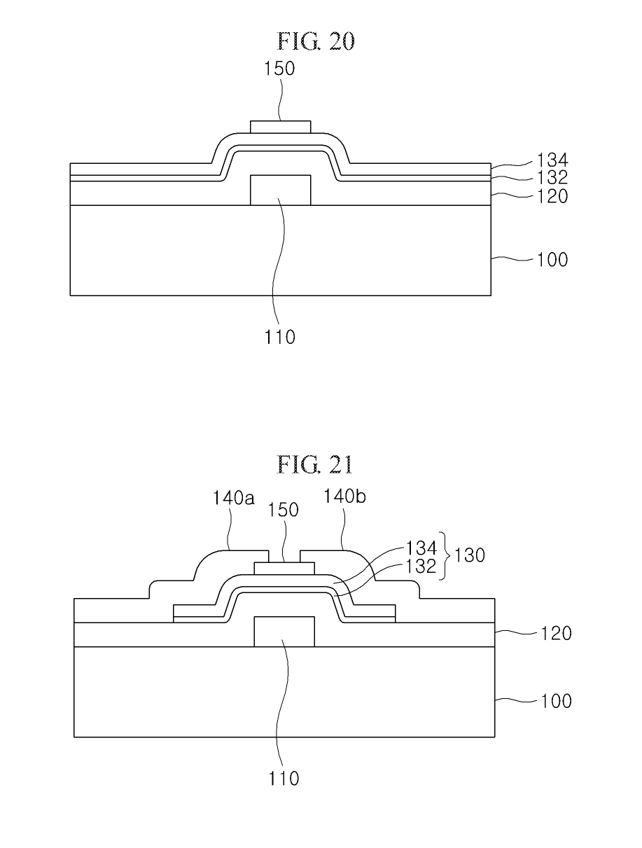

Referring to FIG. 20, a passivation layer 150 is formed on the first and second IGZO thin layers 132 and 134 by using the deposition apparatus illustrated in FIG. 14. The passivation layer 150 is formed to function as an etch stop layer to prevent the first and second IGZO thin layers 132 and 134 from being exposed and damaged in an etch process for forming source and drain electrodes later. Also, the passivation layer 150 may prevent the first and second IGZO thin layers 132 and 134 from being exposed to the atmosphere after the forming of source and drain electrodes is completed later. That is, if the first and second IGZO thin layers 132 and 134 are exposed to the atmosphere, characteristics of the first and second IGZO thin layers 132 and 134 may be degraded due to penetration of moisture, oxygen and the like. Therefore, the passivation layer 150 is formed to prevent penetration of moisture, oxygen and the like. The passivation layer 150 for preventing penetration of moisture or oxygen may be formed of a material having a different etch selectivity from the first and second IGZO thin layers 132 and 134, for example, an insulation layer such as silicon oxide, silicon nitride or the like. Next, a predetermined region of the passivation layer 150 is etched and patterned such that the passivation layer 150 is left on a region between source and drain electrodes spaced apart from each other. At this time, the passivation layer 150 may be patterned to partially overlap the source and drain electrodes.

Referring to FIG. 21, an active layer 130 is formed by patterning the first and second IGZO thin layers 132 and 134 so as to cover the gate electrode 110. Next, a second conductive layer is formed on the active layer 130 and is then patterned by a photo etching process using a predetermined mask to form source electrode 140a and drain electrode 140b. The source electrode 140a and the drain electrode 140b partially overlap an upper surface of the gate electrode 110 and are spaced apart from each other over the gate electrode 110. At this time, the etching process is performed such that the passivation layer 150 is exposed. Herein, the second conductive layer may be formed of any one of metal, metal alloy, metal oxide, a transparent conductive layer and compound thereof by a CVD process. Also, the second conductive layer may be formed in a multilayer structure in consideration of a conductive characteristic and a resistance characteristic. Meanwhile, since the passivation layer 150 is formed between the source electrode 140a and the drain electrode 140b, the first and second IGZO thin layers 132 and 134 can be prevented from being exposed to the atmosphere and thus the characteristics of the first and second IGZO thin layers 132 and 134 can be prevented from being degraded.

Also, the active layer 130 may be formed in a stack structure having three layers of first to third IGZO thin layers formed by three different deposition processes. That is, the first IGZO thin layer may be formed by an ALD process having the process cycle illustrated in FIG. 15, the second IGZO thin layer may be formed by a pseudo ALD process or cyclic CVD process having the process cycle illustrated in FIGS. 16 and 17, and the third IGZO thin layer may be formed by a CVD process. In the above case, the deposition apparatus exemplarily illustrated in FIG. 13 may be used.

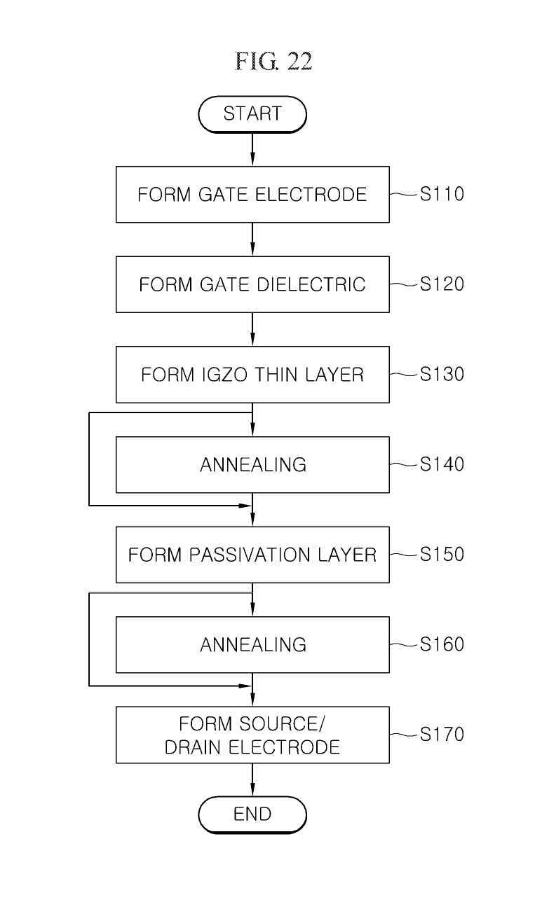

Meanwhile, the passivation layer 150 may be formed in a two-layer structure and an annealing may be performed at least one time before and after the passivation layer 150 is formed. An embodiment regarding the two-layer structure of the passivation layer 150 will now be described with reference to FIG. 22 and FIGS. 23 to 26.

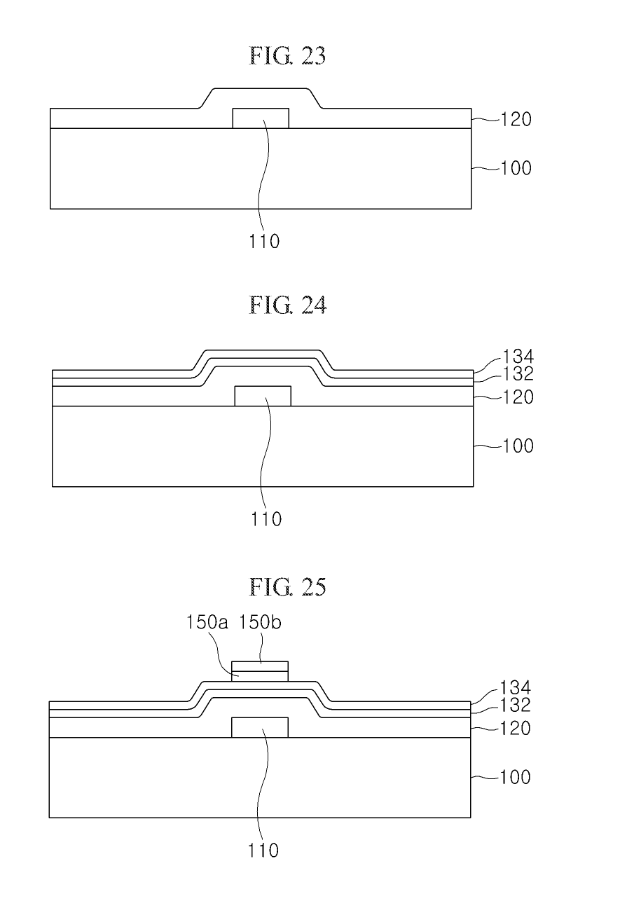

FIG. 22 is a process flow diagram for explaining a method of manufacturing a thin film transistor in accordance with another exemplary embodiment, and FIGS. 23 through 26 are cross-sectional views sequentially illustrating a method of manufacturing a thin film transistor in accordance with another exemplary embodiment. Hereinafter, description that is repetitive of content in previous embodiments will be not given.

Referring to FIGS. 22 and 23, a gate electrode 110 is formed on a predetermined region of a substrate 100, and then a gate dielectric 120 is formed on the entire region the substrate 100 including the gate electrode 110 (S120).

Referring to FIGS. 22 and 24, first and second IGZO thin layers 132 and 134 are formed on the substrate 100 (S130).

Referring to FIGS. 22 and 25, a passivation layer 150 is formed on the first and second IGZO thin layers 132 and 134 (S150). Alternatively, an annealing may be performed before the passivation layer 150 is formed (S140). The annealing is performed to secure off-current after the first and second IGZO thin layers 132 and 134 are formed. The annealing may be performed in a vacuum state under an ambient gas of O₂ or O₃. That is, the annealing may be performed at a pressure lower than atmospheric pressure (760 Torr), preferably, at a pressure ranging from 0.1 Torr to 10 Torr. At this time, the process temperature is maintained in a range of 200° C. to 450° C., and the process time may be in a range of 1 minute to 30 minutes according to characteristics of a device required. Meanwhile, the passivation layer 150 may be formed in a single layer or multilayer structure, and in the case the passivation layer 150 is formed in a multilayer structure, at least one layer is formed by a CVD process. For example, in the case the passivation layer 150 is formed in a two-layer structure comprised of a first passivation layer 150a and a second passivation layer 150b, the first passivation layer 150a is formed by a CVD process using TEOS and O3, and the second passivation layer 150b is formed by a PECVD process using TEOS and O₂. Next, a predetermined region of the passivation layer 150 is etched and patterned such that the passivation layer 150 is left on a region between source and drain electrodes spaced apart from each other. That is, the passivation layer 150 is patterned so as to partially overlap the source and drain electrodes. At this time, an annealing may be performed before the passivation layer 150 is patterned (S 160). Since off-current may be changed after the deposition of the passivation layer 150, the annealing may be performed to compensate for the change of off-current. The annealing may be performed in a vacuum state under an ambient gas of O₂ or O₃. That is, the annealing may be performed at a pressure lower than atmospheric pressure (760 Torr), preferably, at a pressure ranging from 0.1 Torr to 10 Torr. At this time, the process temperature is maintained in a range of 200° C. to 450° C., and the process time may be in a range of 1 minute to 30 minutes according to characteristics of a device required. That is, the annealing may be performed at least one time before and after the formation of the passivation layer 150.

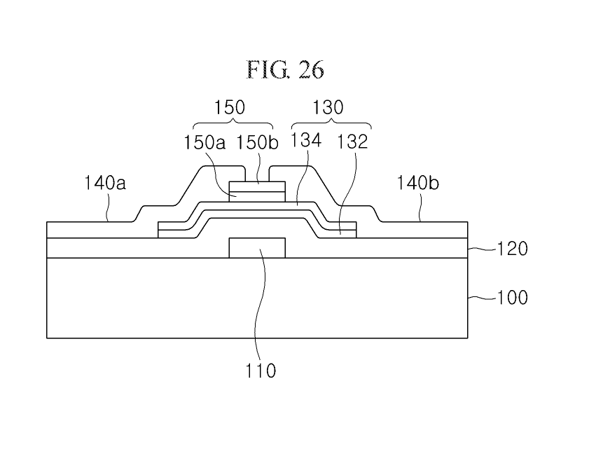

Referring to FIGS. 22 and 26, an active layer 130 is formed by patterning the first and second IGZO thin layers 132 and 134 so as to cover the gate electrode 110. Next, a second conductive layer is formed on the active layer 130 and is then patterned by a photo etching process using a predetermined mask to form source electrode 140a and drain electrode 140b (S170). The source electrode 140a and the drain electrode 140b partially overlap an upper surface of the gate electrode 110 and are spaced apart from each other over the gate electrode 110. The etching process is performed such that the passivation layer 150 is exposed. At this time, since the passivation layer 150 is formed between the source electrode 140a and the drain electrode 140b, the first and second IGZO thin layers 132 and 134 can be prevented from being exposed to the atmosphere and thus the characteristics of the first and second IGZO thin layers 132 and 134 can be prevented from being lowered.

In the above embodiment, the first conductive layer for the gate electrode 110, the gate dielectric 120, and the second conductive layer for the source and drain electrodes 140a and 140b may be formed by a CVD process or a physical vapor deposition (PVD) process. That is, the layers may be formed by sputtering, vacuum evaporation or ion plating. At this time, in the case the layers are formed by a sputtering, the elements of the thin film transistor may be formed by a sputtering process using a sputtering mask (i.e., shadow mask) without a photo etching process using a predetermined mask. Besides the CVD and PVD processes, various coating methods using colloidal solution containing fine particles dispersed therein or sol-gel liquid phase including precursor, for example, a spin coating, a dip coating, an imprinting such as nano imprinting, a stamping, a printing, a transfer printing, etc. may be used to form the foregoing layers. Alternatively, the foregoing layers may be formed by an atomic layer deposition or pulsed laser deposition (PLD) process.

Meanwhile, in addition to the IGZO thin layer, an indium zinc oxide (ITZO) thin layer may be used. That is, the ITZO thin layer may be formed in a multilayer structure having at least two or more layers by using an ALD process and a cyclic CVD process. For example, a first ITZO thin layer may be formed by an ALD process and a second ITZO thin layer may be formed by a CVD process or cyclic CVD process. Also, a first ITZO thin layer may be formed by an ALD process, a second ITZO thin layer may be formed by a pseudo ALD process or cyclic CVD process, and a third ITZO thin layer may be formed by a CVD process. To form an ITZO thin layer as above, the cluster apparatus illustrated in FIG. 12 and the deposition apparatus illustrated in FIG. 13 may be used. In the case the deposition apparatus of FIG. 13 is used, the second source supply part 340 for supplying a gallium source supplies a tin source instead of the gallium source.

Also, an IGZO thin layer and an ITZO thin layer may be stacked. In the case of this stack structure, an ALD process and a cyclic CVD process are also used. For example, the IGZO thin layer may be formed by an ALD process and then the ITZO thin layer may be formed by a cyclic CVD process. Alternatively, a first IGZO thin layer may be formed by an ALD process, a second IGZO thin layer may be formed by a pseudo ALD process or cyclic CVD process, and an ITZO thin layer may be formed by a CVD process. Further, the IGZO thin layer may be formed by an ALD process and then the ITZO thin layer may be formed by a CVD process or cyclic CVD process. That is, while an IGZO thin layer and an ITZO thin layer may be stacked and formed regardless of stack sequence by an ALD process, a CVD process, a pseudo ALD process or a cyclic CVD process, the lowermost layer is formed by the ALD process. Thus, in the case of simultaneously using both of the IGZO thin layer and the ITZO thin layer, the deposition apparatus of FIG. 13 is used, and thus further needs a fifth source supply part for supplying a tin source.

The thin film transistors in accordance with the embodiments of the present disclosure may be used as driving units for driving pixels in displays such as a liquid crystal display, an organic EL display, etc. That is, in a display panel including a plurality of pixels arranged in a matrix configuration, a thin film transistor is formed in each pixel, a pixel is selected through the thin film transistor and data for image display is transferred to the selected pixel.

In embodiments of the present disclosure, at least two-layer-structured IGZO thin layer is formed by using different chemical vapor deposition processes including an atomic layer deposition (ALD) process, and the at least two-layer-structured IGZO thin layer formed is used as an active layer of a thin film transistor. That is, in a total thickness of the IGZO thin layer, the IGZO thin layer of a partial thickness is formed by an ALD process, and the IGZO thin layer of the remaining thickness is formed by using at least one of a chemical vapor deposition (CVD) process, a pseudo ALD process, and a cyclic CVD process. Also, the IGZO thin layer may be formed in a multilayer structure in which each layer has a different composition.

According to the present disclosure, by forming the IGZO thin layer used as an active layer by using a chemical vapor deposition process, the low reliability problem of when the IGZO thin layer is formed by using a related art sputtering, and the problem that the characteristics of the IGZO thin layer are changed as the sputtering progresses can be solved. That is, since the introduced amount of a source can be maintained at a constant rate, the composition of the IGZO thin layer is not changed while the deposition process is progressed, so that the reliability of the IGZO thin layer can be prevented from being lowered.

Also, since the active layer adjacent to a gate dielectric can be formed of IGZO thin layer having superior film quality and interfacial characteristics by using an ALD process and is also used as a front channel, the operation speed of the thin film transistor can be enhanced.

Further, the IGZO thin layer may be formed in a multilayer structure where each layer has a different composition, and thus may be used as a front channel or back channel. That is, composition of indium (In) and gallium (Ga) in a first IGZO thin layer may be made higher than composition of In and Ga in a second IGZO thin layer so that mobility and conductivity of the first IGZO thin layer are higher than the mobility and conductivity of the second IGZO thin layer. Thereby, it is also possible to use the first IGZO thin layer as a front channel and the second IGZO thin layer as a back channel.

In addition, by forming the IGZO thin layer having at least a two-layer structure by using a plurality of processes which are different from each other and including an ALD process, productivity can be enhanced and operation reliability can be guaranteed. That is, in the case where only the ALD process is used, the process speed is slow and thus productivity is low, and in the case where only the CND process is used, the film quality is not dense and thus normal operation is impossible. However, in the case where the ALD process and the CVD process are all used, it is possible to enhance the productivity and guarantee operational reliability.

Meanwhile, by forming a passivation layer on the IGZO thin layer, etching damage of the active layer and a low film quality can be prevented, and by forming at least some of the passivation layer by using a CVD process, damage of the active layer can be prevented. That is, by forming at least some of the passivation layer contacting the active layer by using a CVD or ALD process, damage of the active layer due to plasma can be prevented, and by forming the remaining portion of the passivation layer by using a PECVD process, the film quality and deposition rate of the passivation layer can be enhanced.

Meanwhile, the technical idea of the present disclosure has been specifically described with respect to the preferred embodiments, but it should be noted that the foregoing embodiments are provided only for illustration and not for purposes of limitation. Also, it will be understood by those of ordinary skill in the art that various embodiments may be possible within the scope of technical spirit of the present invention.

1-15. (canceled)

16. A method of manufacturing a thin film transistor comprising:
forming a gate electrode on a substrate and forming a gate dielectric on the substrate including the gate electrode;
forming an active layer on the gate dielectric; and
forming a source electrode and a drain electrode on the active layer,
wherein the active layer comprises a doped zinc oxide thin layer and the doped zinc oxide thin layer is formed in at least a two-layer structure by a chemical vapor deposition process.

17. The method of claim 16, further comprising forming a passivation layer on the active layer to pattern the passivation layer such that the passivation layer is left between the source electrode and the drain electrode.

18. The method of claim 16, wherein the zinc oxide thin layer is doped with at least one of gallium, indium and tin.

19. The method of claim 18, wherein the doped zinc oxide thin layer comprises at least one of an IGZO thin layer and an ITZO thin layer having a multilayer structure comprising at least stacked two layers.

20. The method of claim 19, wherein the doped zinc oxide thin layer comprises a first zinc oxide thin layer formed by an ALD process, and a remaining layer other than the first zinc oxide thin layer formed by at least one of a pseudo ALD process, a cyclic CVD process and a CVD process.

21. The method of claim 20, wherein the first zinc oxide thin layer of the doped zinc oxide thin layer is formed by the ALD process and a second layer is formed by the CVD process.

22. The method of claim 20, wherein the first zinc oxide thin layer of the doped zinc oxide thin layer is formed by the ALD process and a second layer is formed by the cyclic CVD process.

23. The method of claim 20, wherein the first zinc oxide thin layer of the doped zinc oxide thin layer is formed by the ALD process, a second layer is formed by the pseudo ALD process, and a third layer is formed by the CVD process.

24. The method of claim 20, wherein the first zinc oxide thin layer of the doped zinc oxide thin layer is formed by the ALD process, a second layer is formed by the cyclic CVD process, and a third layer is formed by the CVD process.

25. The method of claim 20, wherein the first zinc oxide thin layer and the remaining layer other than the first zinc oxide thin layer are formed with different composition ratios by controlling an introduced amount of a deposition source.

26. The method of claim 21, wherein the first zinc oxide thin layer is has a larger amount of the doped element than the remaining zinc oxide thin layer.

27. The method of claim 22, wherein the first zinc oxide thin layer is higher in mobility and conductivity than the remaining zinc oxide thin layer.

28. The method of claim 17, wherein the passivation layer has a single layer structure or at least a two-layer structure.

29. The method of claim 28, wherein the passivation layer comprises a first passivation layer contacting the active layer, and a remaining second passivation layer, the first passivation layer is formed by a chemical vapor deposition which does not include a plasma, and the second passivation layer is formed by a chemical vapor deposition which uses plasma.

30. The method of claim 29, wherein the first passivation layer is formed using a silicon source and a first reaction source, and the second passivation layer is formed using the silicon source and a second reaction source.

31. The method of claim 30, wherein the silicon source comprises TEOS and/or SiH₄, the first reaction source comprises O₃, and the second reaction source comprises O₂, N₂O, and/or NH₃.

32. The method of claim 31, wherein the first passivation layer is formed using TEOS and O₃.

33. The method of claim 32, wherein the second passivation layer is formed using TEOS or SiH₄ and O₂, N₂O or NH₃.

34. The method of claim 17, further comprising, before and/or after forming the passivation layer, performing an annealing process.

35. The method of claim 34, wherein forming the gate dielectric, forming the active layer, forming the passivation layer, and performing the annealing process are performed in-situ.
